(19) United States
(12) Patent Application Publication
(10) Pub. No.: US 2007/0230236 A1
(43) Pub. Date: Oct. 4, 2007

(54) Semiconductor storage device

(75) Inventors: Yoshiyasu Hirai, Iwata-shi (JP); Yoshihiko Kamata, Yokohama-shi (JP)

Correspondence Address: PILLSBURY WINTHROP SHAW PITTMAN LLP, P.O BOX 10500, McLean, VA, 22102, US

(73) Assignee: Yamaha Corporation, Hamamatsu-shi (JP)

(21) Appl. No.: 11/729,668

(22) Filed: Mar. 29, 2007

(30) Foreign Application Priority Data
Mar. 31, 2006 (JP) 2006-098035

(51) Int. Cl. G11C 11/00

(52) U.S. Cl. 365/154

(57) ABSTRACT

A semiconductor storage device comprises a memory cell array having memory cells arranged in a matrix, each memory cell mainly composed of a flip-flop formed of a pair of cross-coupled inverters, a first wiring configured to each row and each column of the memory cell array and connected to a predetermined power supply node, a second wiring configured in parallel to the first wiring, and a switching circuit that is connected between the power supply node and the second wiring and opens when initial data is set to the memory cells, wherein a receiving node of each pair of inverters is selectively connected to the first wiring or the second wiring in accordance with a logical value of initial data to be set to each one of the plurality of the memory cells belonging to each row and each column of the memory cell array.

### CROSS REFERENCE TO RELATED APPLICATION

This application is based on Japanese Patent Application 2006-098035, filed on Mar. 31, 2006, the entire contents of which are incorporated herein by reference.

### BACKGROUND OF THE INVENTION

A) Field of the Invention

This invention relates to a semiconductor storage device, and more in detail, relates to a static random access memory (SRAM) which is capable of automatically setting initial data to a memory cell.

B) Description of the Related Art

Conventionally, a static random access memory (SRAM) that can set a predetermined initial data to a memory cell is known (refer to Japanese Laid-Open Patent No. 2005-85399).

FIG. 9 shows a structure of a memory cell 1000 equipped to that kind of SRAM. This memory cell 1000 is consisted of a flip-flop formed of a pair of cross-coupled inverters 1001 and 1002, a transfer gate formed of transistors 1004 and 1006, and a transistor 1010 for setting initial data. Moreover, each of the inverters 1001 and 1002 is consisted of a CMOS-type inverter formed of a pair of p-type and n-type MOS transistors.

According to the prior art, a stable condition of the flip-flop formed of the pair of the inverters 1001 and 1002 is compulsory controlled to a specific condition by turning on the n-type MOS transistor 1010 for setting initial data, and thereby initial data is set to the memory cell 1000. For example, when the transistor 1010 is turned on, an input part of the inverter 1002 is driven to a low-level, and therefore, the inverter 1002 drives an input part of the inverter 1001 to a high-level, and the inverter 1001 drives the input part of the inverter 1002 to the low-level. As a result, the flip-flop formed of the pair of the inverters 1001 and 1002 is stabilized in that condition. Therefore, 1-bit data of a logical value (1 or 0) corresponding to the stable condition is set to the memory cell 1000 as initial data.

According to the above-described prior art, because each memory cell consisting a memory cell array is equipped with the transistor 1010 for setting initial data, a number of the transistors consisting the memory cell so that integration will be decreased significantly in the above-described example, one memory cell needs sum of 7 transistors such as two transistors consisting the CMOS-type inverter 1001, two transistors consisting the CMOS-type inverter 1002, two transistors 1004 and 1006 for the transfer gate and the transistor 1010 for setting initial data.

### SUMMARY OF THE INVENTION

It is an object of the present invention to provide a semiconductor storage device that can set initial data to each memory cell without increase in the number of elements in the memory cell.

According to one aspect of the present invention, there is provided a semiconductor storage device, comprising: a memory cell array having memory cells arranged in a matrix, each memory cell mainly composed of a flip-flop formed of a pair of cross-coupled inverters; a first wiring configured to each row and each column of the memory cell array and connected to a predetermined power supply node; a second wiring configured to each row and each column of the memory cell array in parallel to the first wiring; and a switching circuit that is connected between the power supply node and the second wiring and opens when initial data is set to the memory cells, wherein a receiving node of each pair of inverters composing each one of the plurality of the memory cells is selectively connected to the first wiring or the second wiring in accordance with a logical value of initial data to be set to each one of the plurality of the memory cells belonging to each row and each column of the memory cell array.

In the semiconductor storage device, for example, the switching circuit cuts off a current path between the second wiring and the power supply node when the initial data is set to the memory cells, and invalids an operation of one of the pair of inverters by driving the second wiring to an electrical potential which is different from the power supply node.

The semiconductor storage device, for example, further comprises a transistor that has same electrical characteristics with a transistor forming the current path, and is formed between the first wiring and the power supply node.

In the semiconductor storage device, for example, the power supply node is a node for supplying ground potential, and the receiving node is a node for receiving the ground potential. Moreover, in the semiconductor storage device, for example, the power supply node is a node for supplying power supply potential, and the receiving node is a node for receiving the power supply potential.

According to the present invention, initial data can be set to a plurality of memory cells composing a memory cell array without increase in the number of elements in the memory cells.

### BRIEF DESCRIPTION OF THE DRAWINGS

FIG. 1 is a circuit diagram for explaining data storage in a semiconductor storage device according to a first embodiment of the present invention.

FIG. 2 is a circuit diagram for explaining initial data (logical value “1”) setting in the semiconductor storage device according to the first embodiment of the present invention.

FIG. 3 is a circuit diagram for explaining initial data (logical value “0”) setting in the semiconductor storage device according to the first embodiment of the present invention.

FIG. 4 is a circuit diagram showing a structure of a memory array of the semiconductor storage device according to the first embodiment of the present invention.

FIG. 5 is a schematic plan view showing an example of a layout pattern of memory cells according to the first embodiment of the present invention.

FIG. 6 is a cross sectional view showing relationships among wiring layers of the layout pattern of the memory cell and contact regions.

FIG. 7 is a circuit diagram showing a structure of a memory array of the semiconductor storage device according to a second embodiment of the present invention.

FIG. 8 is a timing chart for explaining an operation of the semiconductor storage device relating to the initial data setting according to the second embodiment of the present invention.

FIG. 9 is a circuit diagram showing a structure of a memory cell 1000 equipped to SRAM according to the prior art.

### DETAILED DESCRIPTION OF THE PREFERRED EMBODIMENTS

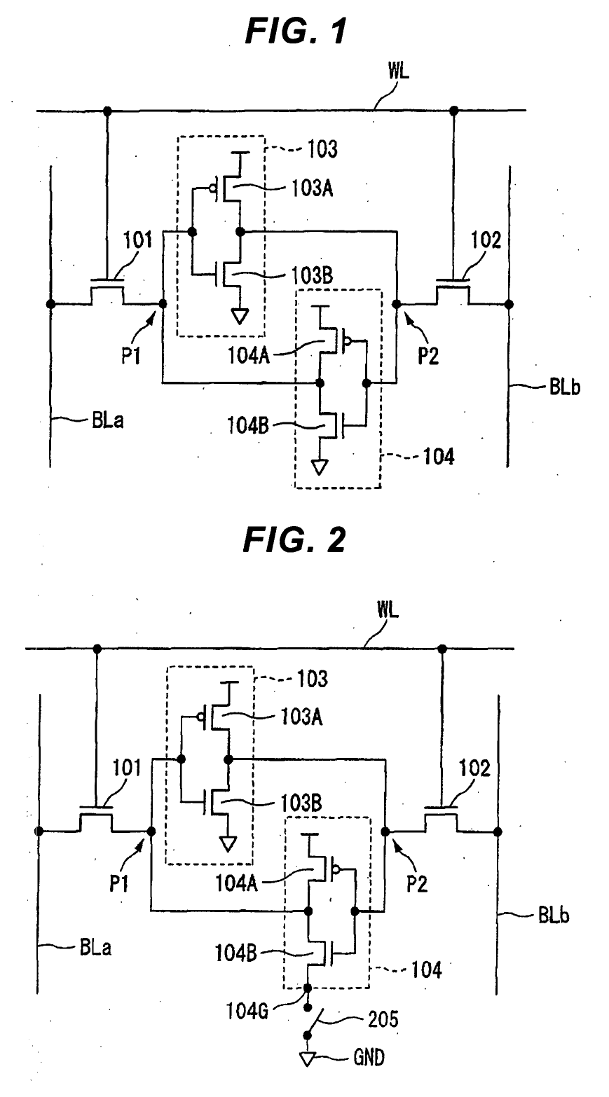

Principles of the embodiments of the present invention will be described with reference to FIG. 1 to FIG. 3.

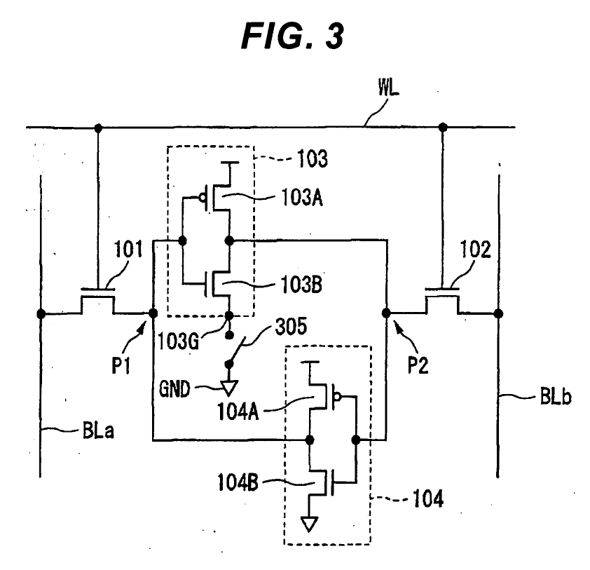

FIG. 1 is a circuit diagram for explaining data storage in a semiconductor storage device according to a first embodiment of the present invention. FIG. 2 is a circuit diagram for explaining initial data (logical value “1”) setting in the semiconductor storage device according to the first embodiment of the present invention. FIG. 3 is a circuit diagram for explaining initial data (logical value “0”) setting in the semiconductor storage device according to the first embodiment of the present invention. In the drawings, same numerals represent same components, and explanations for the same components will not be repeated.

As shown in FIG. 1, a memory cell has same electrical structure as a common SRAM memory cell according to the prior art. For example, the memory cell according to the embodiment of the present invention is mainly composed of a flip-flop formed of a pair of inverters 103 and 104. An output part of the inverter 103 is connected to an input part of the inverter 104 via a connecting point P2, and an output part of the inverter 104 is connected to an input part of the inverter 103 via a connecting point P1; therefore, the pair of the Inverters 103 and 104 are cross-coupled with each other.

The inverter 103 is composed of a p-type MOS transistor 103A and an n-type MOS transistor 103B. A source of the p-type MOS transistor 103A is connected to a power supply, and its drain is connected to a drain of the n-type MOS transistor 103B. A source of the n-type MOS transistor 103B is grounded. Each gate of the p-type MOS transistor 103A and the n-type MOS transistor 103B is connected to the connecting point P1 and each drain of those is connected to the connecting point P2.

The inverter 104 is composed of a p-type MOS transistor 104A and an n-type MOS transistor 104B. A source of the p-type MOS transistor 104A is connected to a power supply, and its drain is connected to a drain of the n-type MOS transistor 104B. A source of the n-type MOS transistor 104B is grounded. Each gate of the p-type MOS transistor 104A and the n-type MOS transistor 104B is connected to the connecting point P2 and each gate of those is connected to the connecting point P1.

An n-type MOS transistor 101 for the transfer gate is connected between the above connecting point P1 and a bit line BLa. That is, either the drain or the source of the n-type MOS transistor 101 is connected to the connecting point P1, and the rest is connected to the bit line BLa, and the gate is connected to the word line WL. Moreover, an n-type MOS transistor 102 for the transfer gate is connected between the above connecting point P2 and the bit line BLb. That is, either the drain or the source of the n-type MOS transistor 102 is connected to the connecting point P1, and the rest is connected to the bit line BLb, and the gate is connected to the word line WL.

According to the memory cell in FIG. 1, the flip-flop composed of the inverters 103 and 104 keeps 1-bit stored data of a logical value “1” or a logical value “0”. On a write mode that is one of normal operation modes, this stored data is supplied from the bit lines BLa and BLb to the above flip-flop via the n-type MOS transistors 101 and 102. For example, the word line WL is selectively driven to the high-level by the low decoder (not shown in the drawings), and the transistors 101 and 102 for the transfer gate are turned on. Then, the high-level is impressed to one of a pair of the bit lines BLa and BLb and the low level is impressed to another corresponding to the logical value of the data to be stored.

For example, when the high-level is impressed to the bit line BLa and the low-level is impressed to another bit line BLb, the high-level is supplied to the connecting point P1 from the bit line BLa via the n-type MOS transistor 101, and the inverter 103 to which the high-level is input outputs the low-level. Moreover, the low-level is supplied to the connecting point P2 from the bit line BLb via the n-type MOS transistor 102, and the inverter 104 to which the low-level is input outputs the high-level. This signal condition in the memory cell is maintained by the flip-flop composed of the inverters 103 and 104 even if the word line WL is driven to the low-level and the memory cell is not selected. By that, 1-bit data corresponding to the signal level of the above bit lines BLa and BLb is stored in the memory cell.

As the above, a basic principle concerning to data maintenance of the memory cell has been described.

In the embodiments of the present invention, for the convenience of the explanation, it is defined that 1-bit data of the logical value “1” is stored when signal levels of the connecting points P1 and P2 in the memory cell are stable respectively at the high-level and the low-level, and it is defined that 1-bit data of the logical value “0” is stored when the signal levels of the connecting points P1 and P2 in the memory cell are stable respectively at the low-level and the high-level.

Next, a principle of the initial data setting of the embodiments of the present invention will be explained. FIG. 2 shows a structure of the memory cell to which the logical value “1” is set as the initial data. FIG. 3 shows a structure of the memory cell to which the logical value “0” is set as the initial data.

When the logical value “1” is set as the initial data, the receiving node (a source of an n-type MOS transistor 104B) 104G of a ground potential of the inverter 104 of the pair of the inverters 103 and 104 composing the flip-flop is separated from the power supply node GND of the ground potential by a switch 205 as shown in FIG. 2. By that, an operation (outputting operation of the low-level) of this inverter 104 will be inactivated, and a stable condition of the flip-flop composed of the inverters 103 and 104 cannot be a condition other than that the connecting point P1 is the high-level and the connecting point P2 is the low-level. Therefore, when the switch 206 is closed iin this condition, the logical value “1” is set as the initial data.

Moreover, when the logical value “0” is set as the initial data, the receiving node (a source of an n-type MOS transistor 103B) 103G of a ground potential of the inverter 103 is separated from the power supply node of the ground potential by a switch 305 as shown in FIG. 3. By that an operation (outputting operation of the low-level) of this inverter 103 will be inactivated, and a stable condition of the flip-flop composed of the inverters 103 and 104 cannot be a condition other than that the connecting point P1 is the low-level and the connecting point P2 is the high-level. Therefore, when the switch 305 is closed in this condition, the logical value “0”, is set as the initial data.

The logical value “1” or “0” can be arbitrary set as the initial data by cutting a supplying path of the ground potential of one of the pair of the inverters composing the flip-flop of the memory cell.

The principle of the initial data setting of the embodiments of present invention has been explained.

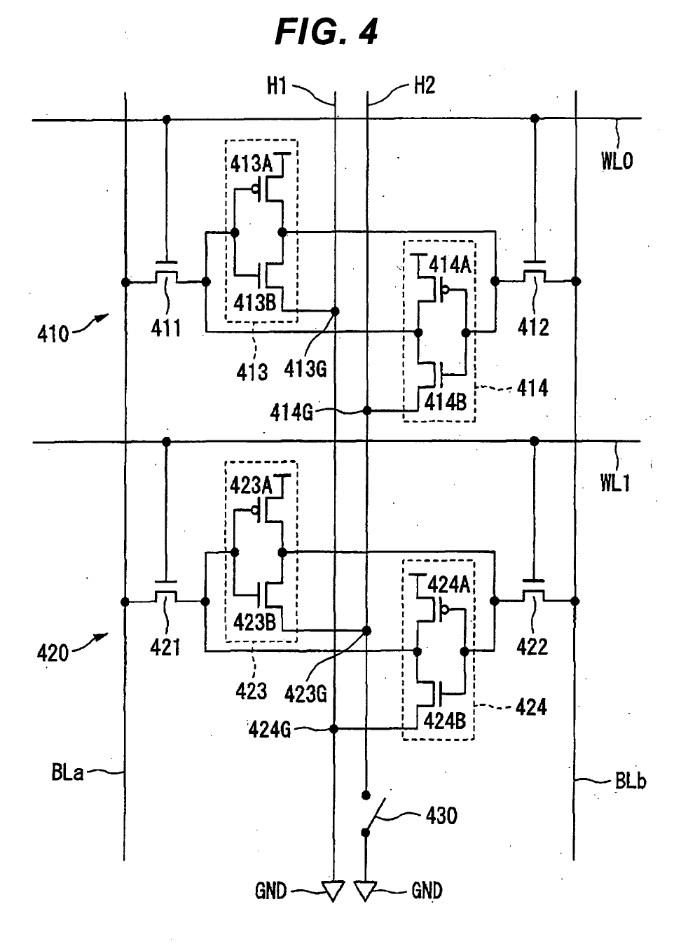

Next, a structure of a memory cell array with which the semiconductor storage device is equipped, to which the above-described principles, according to a first embodiment of the present invention will be explained with reference to FIG. 4.

FIG. 4 shows a part of the memory cell array according to the first embodiment of the present invention, and this memory cell array is composed of memory cells arranged in a matrix and having flip-flop formed of a pair of the inverters. The memory cells 410 and 420 shown in FIG. 4 belong to one column of the memory cell array. The memory cell 410 corresponds to the memory cell shown in FIG. 2. The memory cell 420 corresponds to the memory cell shown in FIG. 3.

For example, n-type MOS transistors 411 and 412 and inverters 413 and 414 for the transfer gate composing the memory cell 410 respectively correspond to the n-type MOS transistors 101 and 102 and the inverters 103 and 104 shown in FIG. 2. Moreover, n-type MOS transistors 421 and 422 and inverters 423 and 424 for the transfer gate composing the memory cell 420 respectively correspond to the n-type MOS transistors 101 and 102 and the inverters 103 and 104 shown in FIG. 3. Furthermore, a switch circuit 430 corresponds to the switches 205 or 305 respectively shown in FIG. 2 and FIG. 3.

Each gate of the n-type MOS transistors 411 and 412 in the memory cell 410 is connected to a word line WL0, and each gate of the n-type MOS transistors 421 and 422 in the memory cell 420 is connected to a word line WL1. Either one of those word lines WL0 and WL0 is selected to be driven to the high-level by a line decoder (not shown in the drawings) in accordance with a line address signal supplied from the outside on a read mode and a write mode.

In each column of the memory cell array, a first wiring H1 and a second wiring H2 are arranged in parallel. The first wiring H1 is connected to a power supply node GND of the ground potential (a predetermined power supply node). The second wiring H2 is connected to the power supply node GND of the ground potential via the switch circuit 430 that is opened when the initial data is set to the memory cells 410 and 420. In accordance with the logical values of the initial data to be set to each one of the plurality of the memory cells 410 and 420, each of the power receiving nodes 413G, 414G, 423G and 424G of the pair of the Inverters composing those memory cells is selectively connected to the first wiring H1 or to the second wiring H2.

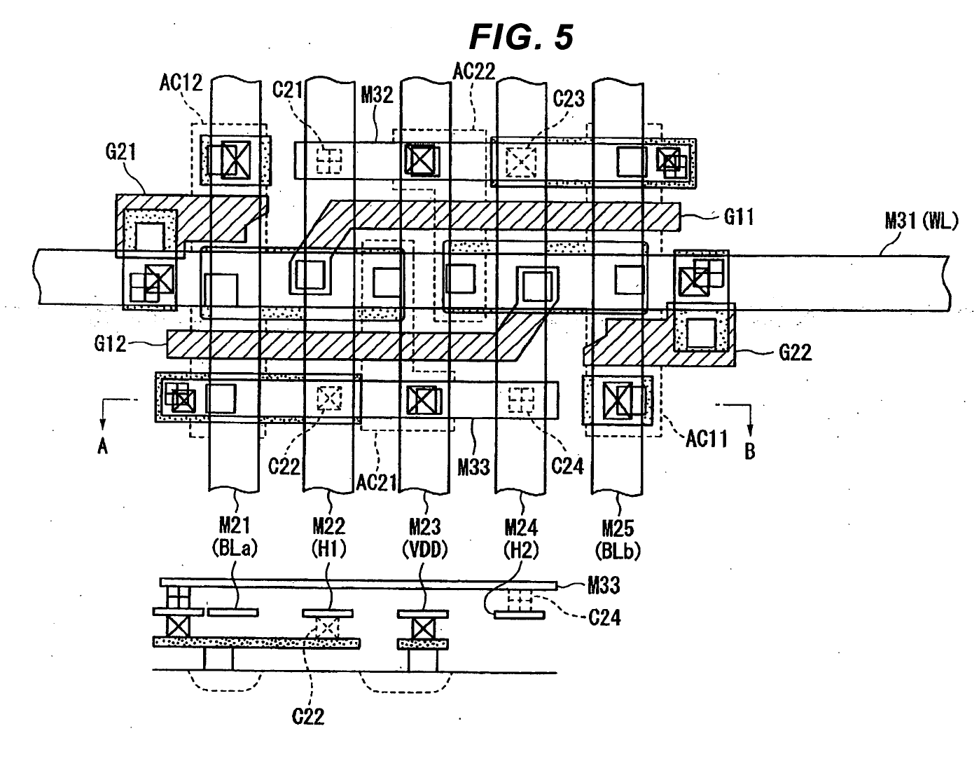

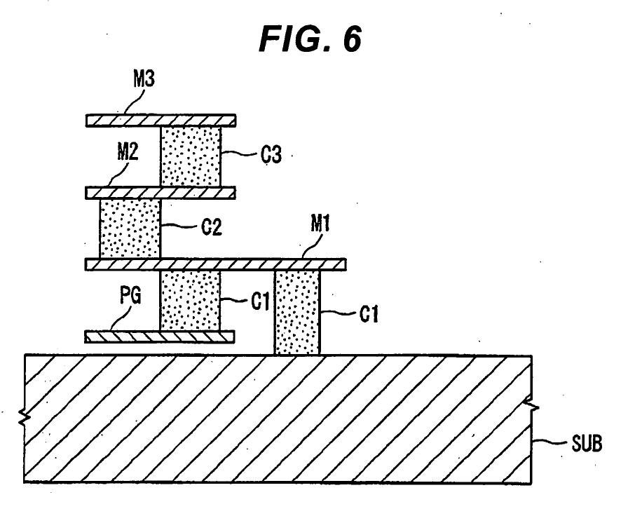

FIG. 5 shows an example of a layout pattern of the memory cells 410 and 420. FIG. 6 shows a connection between each wiring layer and each contact corresponding to the pattern shown in FIG. 5. The layout pattern show in FIG. 5 will be explained by using the memory cell 410 for example. In FIG. 5, a diagram below the layout pattern shows a cross section between A-B in the layout pattern. Moreover, in FIG. 5, a white square represents a first contact, a square with an tinted cross represents a second contact, and a square with a cross represents a third contact.

In FIG. 5, patterns M21, M22, M23, M24, M25 respectively correspond to the bit line BLa, the first wiring H1, the power supply (VDD), the second wiring H2 and the bit line BLb shown in FIG. 4 and correspond to a second wiring layer M2. A pattern M31 corresponds to the word line WL0 and also corresponds to the third wiring layer M3 shown in FIG. 6. A pattern G11 corresponds to each gate of the transistors 413A and 413B composing the inverter 413 shown in FIG. 4 and also corresponds to a poly-silicon layer PG shown in FIG. 6. A pattern G12 corresponds to the transistors 414A and 414B composing the inverter 414 shown in FIG. 4 and also corresponds to the poly-silicon layer PG shown in FIG. 6. Patterns G21 and G22 respectively correspond to each gate of the n-type MOS transistors 411 and 412 for the transfer gate shown in FIG. 4 and also correspond to the poly-silicon layer PG shown in FIG. 6.

A pattern AC11 corresponds to active regions including the sources and drains of the transistors 412 and 413B shown in FIG. 4 and also corresponds to an active region including a diffusion layer (not shown in the drawings) formed on a substrate SUB shown in FIG. 6. A pattern AC12 corresponds to active regions including the sources and drains of the transistors 411 and 414B shown in FIG. 4 and also corresponds to the active region including the diffusion layer (not shown in the drawings) formed on the substrate SUB shown in FIG. 6; A pattern AC21 corresponds to active regions including the source and drain of the transistor 414A shown in FIG. 4 and also corresponds to the active region including the diffusion layer (not shown in the drawings) formed on the substrate SUB shown in FIG. 6. A pattern AC22 corresponds to active regions including the source and drain of the transistor 413A shown in FIG. 4 and also corresponds to the active region including the diffusion layer (not shown in the drawings) formed on the substrate SUB shown in FIG. 6.

The above-described drains of the transistors 414A and 414B and the gate G11 of the transistors 413A and 413B are connected to each other via the first wiring layer M1, and the above-described drains of the transistors 413A and 413B and the gate G12 of the transistors 414A and 414B are connected to each other via the first wiring layer M1. The source (receiving node 414G) of the above-described transistor 414B is connected to the second wiring H2 (shown in FIG. 4) formed of the second wiring layer M2 via the first wiring layer M1 shown in FIG. 6 via a pattern M33 (the third wiring layer) and the third contact C24 shown in FIG. 5. The source (receiving node 413G) of the above-described transistor 413B is connected to the first wiring H1 (shown in FIG. 4) formed of the second wiring layer M2 via the first wiring layer M1 shown in FIG. 6 via a pattern M32 (the third wiring layer) and the third contact C21 shown in FIG. 5.

According to this layout pattern, the logical value “1” or “0” is programmed to this memory cell by forming one of the second contacts C21 and C24 and the second contacts C22 and C23.

The example of the layout pattern has been explained.

According to the structure of the memory cell array in FIG. 4, when the initial data is set, the receiving node 414G of the inverter 414 of the memory cell 410 and the receiving node 423G of the inverter 423 of the memory cell 420 are electrically isolated from the power supply node GND of the ground potential by controlling the switch circuit 430 to open by the controlling circuit (not shown in the drawings), and the ground potential will not be supplied to these receiving nodes. Therefore, as explained with reference to FIG. 2 and FIG. 3, the logical value “1” and “0” are set to these memory cells 410 and 420 as the initial data.

Moreover, in the first embodiment of the present invention, although the example of the case that the initial data is set to two memory cells 410 and 420 has been explained, when the above described receiving nodes in all the memory cells belong to the same column of the memory cell are connected selectively to the first wiring H1 or the second wiring H2, initial data can be set in the memory cell independently from other memory cells in the same column. Moreover, in the first embodiment of the present invention, although the first wiring H1 and the second wiring H2 are arranged in each column, they can be arranged in each line. By that, the initial data can be set to the memory cell independently from the other memory cells in the same line. In the second embodiment of the present invention described in the below, the same concept can be applied.

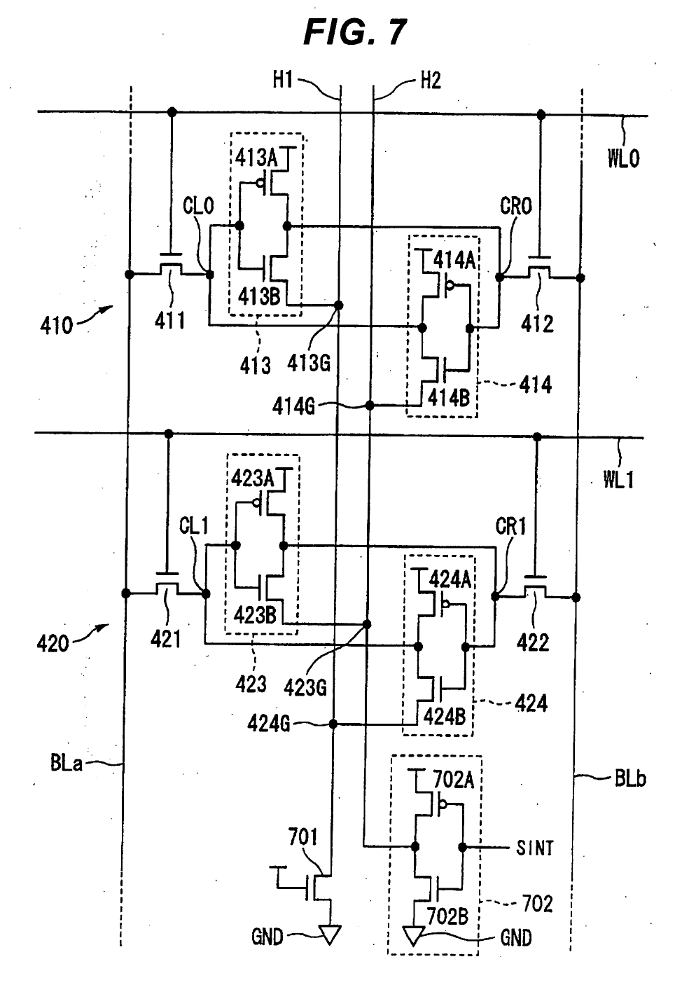

Next, a structure of a memory cell array equipped with which a semiconductor storage device according to the second embodiment of the present invention is equipped will be explained with reference to FIG. 7. In FIG. 7, the same reference numbers and symbols as those in FIG. 4 are representing the similar components to the first embodiment shown in FIG. 4 in the above.

As shown in FIG. 7, the semiconductor storage device according to the second embodiment of the present invention has a CMOS-type inverter 702 composed of a p-type MOS transistor 702A and an n-type MOS transistor 702B. A source of the p-type MOS transistor 702A is connected to a power supply, and a drain is connected to a drain of the n-type MOS transistor 702B, and a source of the n-type MOS transistor 702B is connected to a power supply node GND of ground potential.

Each drain of the p-type MOS transistor 702 and the n-type MOS transistor 702B is connected to the second wiring H2 as the output part of this inverter 702, and an initializing signal SINT is commonly impressed to each gate of these transistors.

Since the electric current path of the n-type MOS transistor 702B is inserted between the second wiring H2 and the power supply node GND of the ground potential, this n-type MOS transistor 702B works as the switch circuit to open when setting the initial data to the memory cells 410 and 420 as same as the switch circuit 430 shown in FIG. 4.

Moreover, in the second embodiment of the present invention, an n-type MOS transistor 701 having the same electrical characteristics as the above-described transistor 702B is inserted between the first wiring H1 and the power supply node GND of the ground potential as a dummy transistor. For example, a drain of the n-type MOS transistor 701 is connected to the first wiring H1, a source is connected to the power supply node GND of the ground potential, and a gate is connected to the power source. This n-type MOS transistor 701 is for making electrical characteristics of the first wiring H1 and the second wring H2 toward the power supply node GND of the ground potential the same in a normal operation mode and for preventing unbalance of the electrical characteristics of these wirings from giving an influence to data maintenance characteristics of the memory cell.

In the second embodiment of the present invention, the initializing signal SINT is fixed to the high-level in the normal operation mode, and t the n-type MOS transistor 702B of the inverter 702 supplies the ground potential to the second wiring H2. At this time, although the n-type MOS transistor 702B that is turned on exists between the second wiring H2 and the power supply node GND of the ground potential, because the n-type MOS transistor 701 having the same electrical characteristics as the n-type MOS transistor 702B exists between the first wiring H1 and the power supply node GND, seeing the memory cell array as a whole, symmetry of the electrical characteristics of the pair of the inverters composing the flip-flop n each memory cell is maintained, and the data maintenance characteristics of the memory cell is well maintained.

Moreover, in a setting operation of the initial data, the initializing signal is fixed to the low-level. By that, the n-type MOS transistor 702B is turned off, and the electric current path between the second wiring and the power supply node GND of the ground potential is cut, and the p-type MOS transistor 702A is turned on, and the second wiring H2 is driven to the high-level. In this case, the initial data can be set because the stability of the flip-flop in each memory cell becomes unified as same as in the above-described first embodiment.

Moreover, according to the embodiment of the present invention. The stability of the flip-flop in each memory cell can be controlled to a single condition certainly, comparing to the first embodiment, by driving the second wiring H2 to the high-level at the time of setting the initial data. Therefore, the initial data can be set stably.

As described in the above, when the initial data is set to the memory cell, the switch circuit 702 of the second embodiment cuts the electric current path between the second wiring H2 and the power supply node GND of the ground potential by turning off the n-type MOS transistor 702B, the second wiring is driven to electric potential of a different power supply (VDD) from the electric potential of the power supply node GND, and the operation (the low-level output operation) of one of the pair of the inverters in each memory cell is inactivated by turning on the p-type MOS transistor 702A.

Moreover, in FIG. 7, connecting points CL0 and CR0 in the memory cell 410 respectively correspond to the connecting points P1 and P2 in FIG. 2, and connecting points CL1 and CR1 in the memory cell 420 respectively correspond to the connecting points P1 and P2 shown in FIG. 3.

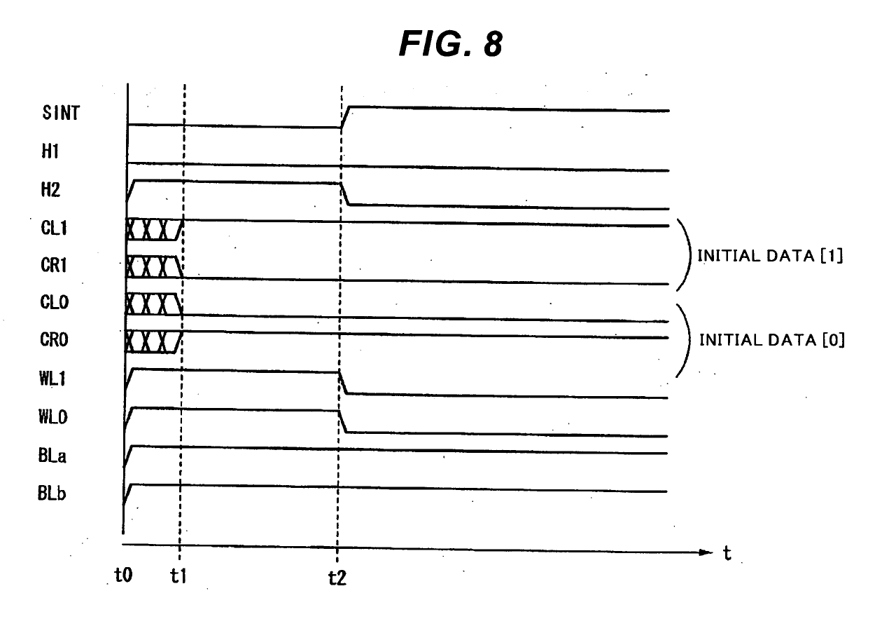

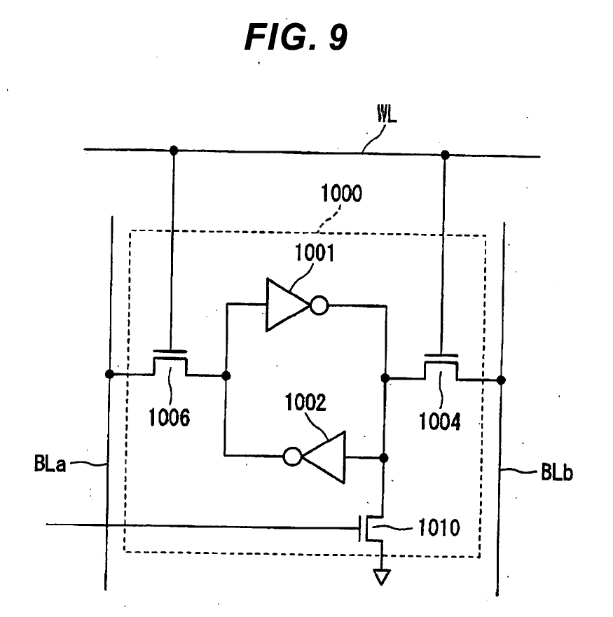

Next, the operation of the second embodiment is explained with reference to a timing chart shown in FIG. 8. At timing to, the power source is turned on, the low-level is supplied to the signal SINT, the high-level is supplied to the word lines WL0 and WL1, and the high-level is supplied to the bit lines BLa and BLb. In addition to that, the n-type MOS transistor 702B is turned off, and the p-type MOS transistor 702A is turned on. As a result, the first wiring H1 is driven to the low-level by the n-type MOS transistor 702A, and the second wiring H2 is driven to the high-level by the >type MOS transistor 702A.

When the power supply is established at timing 1, the connecting point CR1 in the memory cell 420 is fixed to the high-level by an influence of each signal level of the first wring H1 and the second wiring H2, and the connecting point CL1 is fixed to the low-level. On the other hand, the connecting point CL0 in the memory cell 410 is fixed to the high-level, and the connecting point CR0 is fixed to the low-level.

As described in the above, the logical value “1” set to the memory cell 410 and the logical value “1” is set to the memory cell 420 as the initial data.

Then, when the high-level is supplied to the signal SINT at timing t2, the low-level is supplied to the word lines WL0 and WL1, thereafter the first wiring H1 and the second wiring H2 are driven to the low-level respectively by the n-type MOS transistor 701 and 702B, and the normal ground potential is supplied to each memory cell. By this, the normal operation can be executed.

According to each embodiment of the present invention, unique initial data can be set to each memory cell in the memory cell array without increasing the number of the elements of the memory cell. Moreover, for example, if it is used as a RAM inside of a musical tone generator, a predetermined musical tone can be pronounced immediately after turning on the power source without initial setting, and also the initial data can be used after changing a part of it. Moreover, since it is unnecessary to equip with a CPU and a ROM for setting the initial data inside the musical tone generator, a chip size can be small. Moreover, when a program that can operate stably is programmed in this semiconductor storage device as the initial data, it is possible to automatically restore a stable condition by reading this program when detecting abnormality.

According to the embodiments of the present invention, the initial data is set in the memory cell by inactivating the operation (output operation of the low-level) of one of the pair of the inverters composing the flip-flop of the memory cell.

Moreover, one switch circuit for inactivating the operation of one Inverter composing the flip-flop of each memory cell is equipped for the plurality of the memory cells. In other words, one switch circuit is shared by the plurality of the memory cells.

Further, the initial data is programmed in the memory cell by patterns (for example, patterns of wiring and contact) on layout of the pair of the inverters composing the flip-flop in the memory cell.

Furthermore, a transistor that is same as a transistor inserted to the power supply of the inverter to be inactivated while initializing is inserted to the power supply that is activated while initializing for maintaining a balance.

Furthermore, the receiving node level of the inverter to be inactivated while initializing is set opposite to the level in the normal operation. For example, the power supply electric potential is supplied to the receiving node of the ground potential of the inverter to inactivate this inverter. On the contrary, the ground potential is supplied to the receiving node of the power supply electric potential of the inverter to inactivate this inverter.

Furthermore, by connecting a reset signal on an LSI to the initializing signal of the memory, a circuit or a sequence for executing the initial setting can be omitted from a controlling circuit such as a CPU.

Furthermore, by connecting an abnormality detecting signal to the initializing signal of the memory, automatically return from the abnormal condition can be executed.

The present invention has been described in connection with the preferred embodiments. The invention is not limited only to the above embodiments, it is apparent that various modifications, improvements, combinations, and the like can be made by those skilled in the art.

For example, in the embodiments of the present invention, although the initial data is set to the memory cell by cutting the electric current path between the memory cell and power supply node GND of the ground potential, the initial data may be set by cutting the electric current path between the memory cell and the power supply node (VDD) of the power supply electric potential. In this case, the initial data is set by inactivating the output operation of the high-level of one inverter of the pair of the inverters composing the memory cell.

Moreover, in this specification, the power supply node of the ground potential is taken in the broad sense of a power supply.

What are claimed are:

1. A semiconductor storage device, comprising:
a memory cell array having memory cells arranged in a matrix, each memory cell mainly composed of a flip-flop formed of a pair of cross-coupled inverters;
a first wiring configured to each row and each column of the memory cell array and connected to a predetermined power supply node;
a second wiring configured to each row and each column of the memory cell array in parallel to the first wiring; and
a switching circuit that is connected between the power supply node and the second wiring and opens when initial data is set to the memory cells,
wherein a receiving node of each pair of inverters composing each one of the plurality of the memory cells is selectively connected to the first wiring or the second wiring in accordance with a logical value of initial data to be set to each one of the plurality of the memory cells belonging to each row and each column of the memory cell array.

2. The semiconductor storage device according to claim 1, wherein the switching circuit cuts off a current path between the second wiring and the power supply node when the initial data is set to the memory cells, and invalids an operation of one of the pair of inverters by driving the second wiring to an electrical potential which is different from the power supply node.

3. The semiconductor storage device according to claim 2, further comprising a transistor that has same electrical characteristics with a transistor forming the current path, and is formed between the first wiring and the power supply node.

4. The semiconductor storage device according to claim 1, wherein the power supply node is a node for supplying ground potential, and the receiving node is a node for receiving the ground potential.

5. The semiconductor storage device according to claim 1, wherein the power supply node is a node for supplying power supply potential, and the receiving node is a node for receiving the power supply potential.
